(19) United States
(12) Patent Application Publication
(10) Pub. No.: US 2024/0397714 A1
(43) Pub. Date: Nov. 28, 2024

(54) SEMICONDUCTOR MEMORY DEVICE AND METHOD OF MANUFACTURING THE SEMICONDUCTOR MEMORY DEVICE

(71) Applicant: SK hynix Inc., Icheon-si Gyeonggi-do (KR)

(72) Inventor: Sung Wook JUNG, Icheon-si Gyeonggi-do (KR)

(73) Assignee: SK hynix Inc., Icheon-si Gyeonggi-do (KR)

(21) Appl. No.: 18/499,985

(22) Filed: Nov. 1, 2023

(30) Foreign Application Priority Data
May 23, 2023 (KR) 10-2023-0066024

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80895; H01L 2224/80896; H01L 2924/1431; H01L 2924/14511

(57) ABSTRACT

Provided herein is a semiconductor memory device and a method of manufacturing the semiconductor memory device. The semiconductor memory device may include a gate stacked body in which a plurality of interlayer insulating layers and a plurality of conductive patterns are alternately stacked, and a plurality of channel structures disposed to extend in a vertical direction in the gate stacked body disposed in a cell region, wherein the plurality of conductive patterns extend in a horizontal direction in the cell region, and extend in the vertical direction or in a direction between the vertical direction and the horizontal direction in a word line contact region adjacent to the cell region.

### CROSS-REFERENCE TO RELATED APPLICATION

The present application claims priority under 35 U.S.C. § 119 (a) to Korean patent application number 10-2023-0066024 filed on May 23, 2023, in the Korean Intellectual Property Office, the entire disclosure of which is incorporated by reference herein.

### BACKGROUND

### 1. Technical Field

Various embodiments of the present disclosure generally relate to an electronic device, and more particularly, to an electronic device including a semiconductor memory device having a vertical channel structure and a method of manufacturing the semiconductor memory device.

### 2. Related Art

Recently, the paradigm for a computer environment has been converted into ubiquitous computing so that computer systems can be used anytime and anywhere. Due to this, the use of portable electronic devices such as mobile phones, digital cameras, and notebook computers has rapidly increased. In general, such portable electronic devices use a memory system which employs a semiconductor memory device, in other words, use a data storage device. The data storage device is used as a main memory device or an auxiliary memory device for portable electronic devices.

The data storage device using a semiconductor memory device is advantageous in that, since there is no mechanical driving part, stability and durability are excellent, an information access speed is high, and power consumption is low. The data storage device, as examples of the memory system having such advantages, includes a universal serial bus (USB) memory device, memory cards having various interfaces, a solid state drive (SSD), etc.

Semiconductor memory devices are roughly classified into a volatile memory device and a nonvolatile memory device.

The nonvolatile memory device has relatively low write and read speeds, but retains data stored therein even when the supply of power is interrupted. Therefore, the nonvolatile memory device is used to store data to be retained regardless of whether power is supplied. Examples of the nonvolatile memory device include a read-only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. The flash memory is classified into a NOR type and a NAND type.

### SUMMARY

An embodiment of the present disclosure may provide for a semiconductor memory device. The semiconductor memory device may include a gate stacked body in which a plurality of interlayer insulating layers and a plurality of conductive patterns are alternately stacked, and a plurality of channel structures disposed to extend in a vertical direction in the gate stacked body disposed in a cell region, wherein the plurality of conductive patterns extend in a horizontal direction in the cell region, and extend in the vertical direction or in a direction between the vertical direction and the horizontal direction in a word line contact region adjacent to the cell region.

An embodiment of the present disclosure may provide for a semiconductor memory device. The semiconductor memory device may include a gate stacked body formed in a cell region and in a word line contact region adjacent to the cell region in a horizontal direction, and a plurality of channel structures disposed to extend in a vertical direction in the gate stacked body disposed in the cell region, wherein the gate stacked body includes a plurality of interlayer insulating layers and a plurality of conductive patterns that are alternately stacked, and wherein the plurality of conductive patterns extend in the horizontal direction in the cell region, and extend in the vertical direction or in a direction between the vertical direction and the horizontal direction in the word line contact region and are then exposed to an upper surface of the gate stacked body.

An embodiment of the present disclosure may provide for a method of manufacturing a semiconductor memory device. The method may include forming a buffer layer on a substrate including a cell region and a word line contact region, forming a trench by etching the buffer layer and the substrate in the word line contact region to a certain depth, forming a stacked body, in which first material layers and second material layers are alternately stacked, on an entire structure, wherein the stacked body is formed along a sidewall and a lower surface of the trench and formed such that an upper surface of the stacked body in the word line contact region is lower than a lower surface of the buffer layer in the cell region, forming a plurality of channel structures extending in a vertical direction in the stacked body and the buffer layer in the cell region, replacing the second material layers with third material layers that are conductive patterns, removing the substrate such that the lower surface of the buffer layer is exposed, and removing a portion of the stacked body disposed at a position lower than the lower surface of the buffer layer, together with the substrate, thus exposing the third material layers, and forming contacts coupled to the exposed third material layers, respectively.

### BRIEF DESCRIPTION OF THE DRAWINGS

FIG. 1 is a block diagram illustrating a semiconductor memory device according to an embodiment of the present disclosure.

FIG. 2 is a circuit diagram for explaining a memory cell array of FIG. 1.

FIG. 3 is a perspective view schematically illustrating a semiconductor memory device according to an embodiment of the present disclosure.

FIG. 4 is a sectional view for explaining the memory cell array of FIG. 1.

FIGS. 5A, 5B, 5C, 5D, 5E, 5F, 6, 7, 8A, and 8B are sectional views and a plan view for explaining a method of manufacturing a semiconductor memory device according to an embodiment of the present disclosure.

FIG. 9 is a block diagram illustrating the configuration of a memory system according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure will now be described in detail with reference to the accompanying drawings so that those skilled in the art can practice the technical spirit of the present disclosure.

Various embodiments of the present disclosure are directed to a semiconductor memory device, in which conductive patterns enclosing a vertical channel structure can be coupled to contacts, and a method of manufacturing the semiconductor memory device.

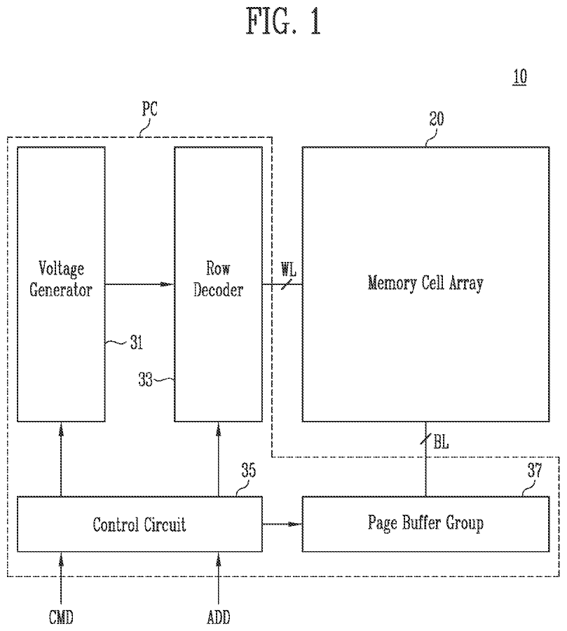

FIG. 1 is a block diagram illustrating a semiconductor memory device according to an embodiment of the present disclosure.

Referring to FIG. 1, a semiconductor memory device 10 includes a peripheral circuit PC and a memory cell array 20.

The peripheral circuit PC may control a program operation of storing data in the memory cell array 20, a read operation of outputting data stored in the memory cell array 20, and an erase operation of erasing data stored in the memory cell array 20.

In an embodiment, the peripheral circuit PC may include a voltage generator 31, a row decoder 33, a control circuit 35, and a page buffer group 37.

The memory cell array 20 may include a plurality of memory blocks. The memory cell array 20 may be coupled to the row decoder 33 through word lines WL, and may be coupled to the page buffer group 37 through bit lines BL.

The control circuit 35 may control the voltage generator 31, the row decoder 33, and the page buffer group 37 in response to a command CMD and an address ADD.

The voltage generator 31 may generate various operating voltages, such as an erase voltage, a ground voltage, a program voltage, a verify voltage, a pass voltage, and a read voltage, which are used for a program operation, a read operation, and an erase operation, under the control of the control circuit 35.

The row decoder 33 may select a memory block under the control of the control circuit 35. The row decoder 33 may apply the operating voltages to the word lines WL coupled to the selected memory block.

The page buffer group 37 may be coupled to the memory cell array 20 through the bit lines BL. The page buffer group 37 may store data received from an input/output circuit (not illustrated) under the control of the control circuit 35 during a program operation. The page buffer group 37 may sense voltages or currents of the bit lines BL under the control of the control circuit 35 during a read operation or a verify operation. The page buffer group 37 may select the bit lines BL under the control of the control circuit 35.

Structurally, the memory cell array 20 may overlap a part of the peripheral circuit PC.

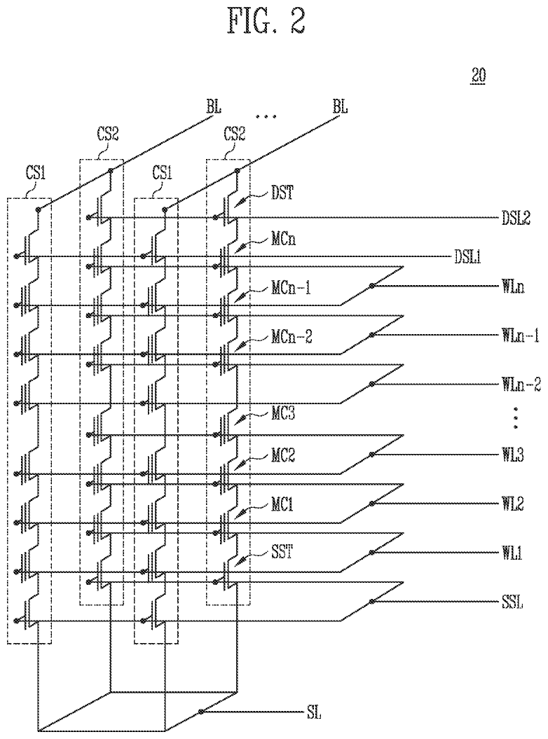

FIG. 2 is a circuit diagram for explaining the memory cell array of FIG. 1.

Referring to FIG. 2, the memory cell array 20 may include a plurality of cell strings CS1 and CS2 coupled between a source line SL and a plurality of bit lines BL. The plurality of cell strings CS1 and CS2 may be coupled in common to a plurality of word lines WL1 to WLn.

Each of the plurality of cell strings CS1 and CS2 may include at least one source select transistor SST coupled to the source line SL, at least one drain select transistor DST coupled to the corresponding bit line BL, and a plurality of memory cells MC1 to MCn coupled in series to each other between the source select transistor SST and the drain select transistor DST.

Gates of the plurality of memory cells MC1 to MCn may be respectively coupled to the plurality of word lines WL1 to WLn stacked to be spaced apart from each other. The plurality of word lines WL1 to WLn may be arranged between a source select line SSL and two or more drain select lines DSL1 and DSL2. The two or more drain select lines DSL1 and DSL2 may be spaced apart from each other at the same level.

A gate of the source select transistor SST may be coupled to the source select line SSL. A gate of the drain select transistor DST may be coupled to the drain select line DSL1 or DSL2 corresponding to the drain select transistor DST.

The source line SL may be coupled to a source of the source select transistor SST. A drain of the drain select transistor DST may be coupled to a bit line BL corresponding to the drain select transistor DST.

The plurality of cell strings CS1 and CS2 may be divided into cell string groups coupled to the two or more drain select lines DSL1 and DSL2, respectively. Cell strings coupled to the same word line and the same bit line may be independently controlled by different drain select lines. Further, cell strings coupled to the same drain select line may be independently controlled by different bit lines.

In an embodiment, two or more drain select lines DSL1 and DSL2 may include a first drain select line DSL1 and a second drain select line DSL2. The plurality of cell strings CS1 and CS2 may include first cell strings CS1 of a first cell string group coupled to the first drain select line DSL1 and second cell strings CS2 of a second cell string group coupled to the second drain select line DSL2.

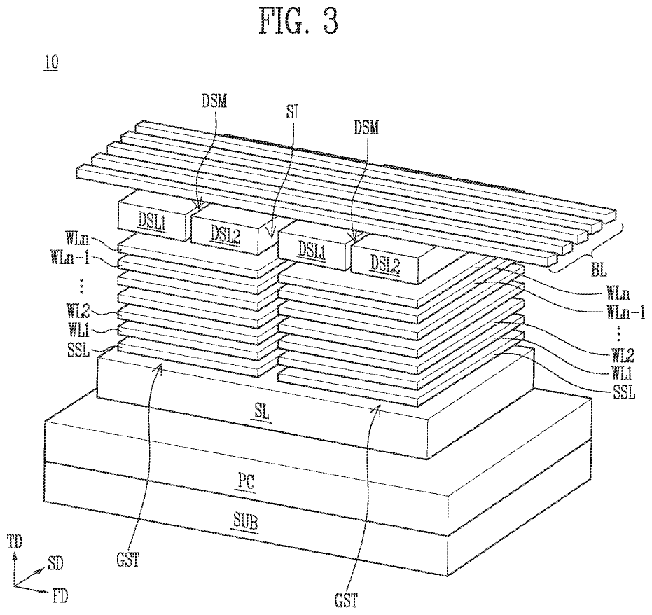

FIG. 3 is a perspective view schematically illustrating a semiconductor memory device according to an embodiment of the present disclosure.

Referring to FIG. 3, a semiconductor memory device 10 may include a peripheral circuit PC arranged on a substrate SUB and gate stacked bodies GST overlapping the peripheral circuit PC.

Each of the gate stacked bodies GST may include a source select line SSL, a plurality of word lines WL1 to WLn, and two or more drain select lines DSL1 and DSL2 separated from each other at the same level by a separation structure DSM.

The source select line SSL and the plurality of word lines WL1 to WLn may extend in a first direction FD and a second direction SD, and may be formed in planar shapes parallel to each other on the upper surface of the substrate SUB. The first direction FD and the second direction SD may be directions parallel to the substrate SUB, and the first direction FD and the second direction SD may be orthogonal to each other. For example, the first direction FD may be a direction in which the X axis of an XYZ coordinate system faces, and the second direction SD may be a direction in which the Y axis of the XYZ coordinate system faces.

The plurality of world lines WL1 to WLn may be stacked to be spaced apart from each other in a third direction TD. The third direction TD may be a direction that is vertical to the substrate SUB and orthogonal to the first direction FD and the second direction SD. For example, the third direction TD may be a direction in which the Z axis of the XYZ coordinate system faces. The plurality of word lines WL1 to WLn may be arranged between the two or more drain select lines DSL1 and DSL2 and the source select line SSL.

The gate stacked bodies GST may be separated from each other by a slit SI. The separation structure DSM may be formed to be shorter than the slit SI in the third direction TD, and may overlap the plurality of word lines WL1 to WLn.

Each of the separation structure DSM and the slit SI may extend in a linear shape, a zigzag shape, or a wave shape. The width of each of the separation structure DSM and the slit SI may be variously changed depending on the design rule.

The source select line SSL according to an embodiment may be arranged closer to the peripheral circuit PC than the two or more drain select lines DSL1 and DSL2.

The semiconductor memory device 10 may include a source line SL disposed between the gate stacked bodies GST and the peripheral circuit PC and a plurality of bit lines BL spaced farther apart from the peripheral circuit PC than the source line SL. The gate stacked bodies GST may be disposed between the plurality of bit lines BL and the source line SL.

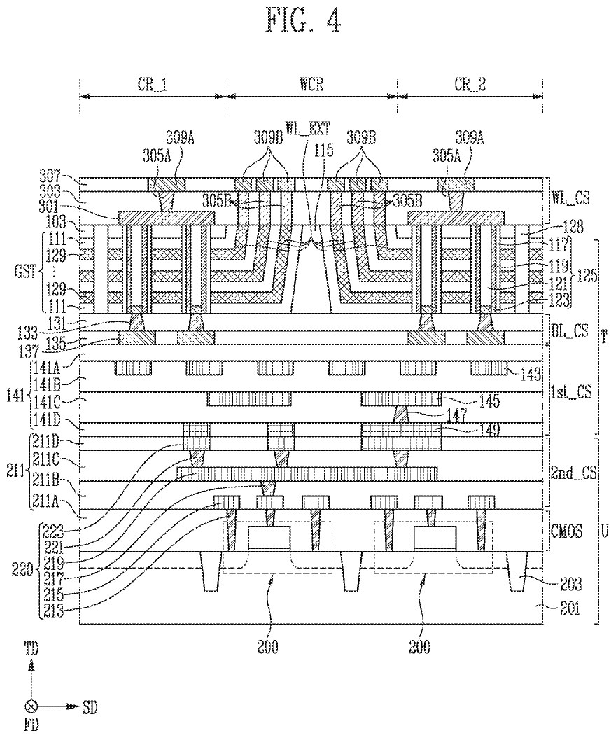

FIG. 4 is a sectional view for explaining the memory cell array of FIG. 1.

Referring to FIG. 4, the memory cell array may be configured such that a lower structure U and an upper structure T are adhered to each other, and a word line connection structure WL_CS may be disposed on the upper structure T. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

The upper structure T may include gate stacked bodies GST separated by an insulating pattern 128 and an insulating layer 115, channel structures 125 penetrating the gate stacked bodies GST to extend in a third direction TD, and a bit line connection structure BL_CS and a first coupling structure 1st_CS that are disposed under the gate stacked bodies GST. The insulating pattern 128 and the insulating layer 115 may extend in the third direction TD, and the gate stacked body GST in a first cell region CR_1 and the gate stacked body GST in a second cell region CR_2 may be physically separated from each other by the insulating layer 115.

Each gate stacked body GST may include first material layers 111 and third material layers 129, which are alternately stacked in a vertical direction. The first material layers 111 may be defined as interlayer insulating layers, and the third material layers 129 may be defined as conductive patterns for word lines. Each of the third material layers 129 may include various conductive materials, such as a doped silicon layer, a metal layer, a metal silicide layer, and a barrier layer, and may include two or more kinds of conductive materials. For example, each of the third material layers 129 may include tungsten and a titanium nitride layer (TiN) configured to enclose the surface of tungsten. Tungsten is a low-resistance material and is capable of decreasing the resistance of the third material layers 129. The titanium nitride layer (TiN) may be a barrier layer, and may prevent tungsten and the interlayer insulating layers from directly contacting each other. Each of the third material layers 129 may extend in a second direction SD, which is a horizontal direction, in the first cell region CR_1 and the second cell region CR_2, and may extend in a third direction TD, which is a vertical direction, or in a direction between the third direction TD and the second direction SD in a word line contact region WCR between the first cell region CR_1 and the second cell region CR_2, and may then be exposed to the upper surface of the corresponding gate stacked body GST. The third material layers 129 extending in the third direction TD or in the direction between the third direction TD and the second direction SD and exposed to the upper surfaces of the gate stacked bodies GST may be defined as word line extensions WL_EXT. The third material layers 129 extending in the second direction SD, which is the horizontal direction, in the first cell region CR_1 and the second cell region CR_2 and the word line extensions WL_EXT extending in the third direction TD, which is the vertical direction, or in the direction between the third direction TD and the second direction SD in the word line contact region WCR may be made of the same material. The word line extensions WL_EXT may extend to the position equal to or higher than that of the upper surface of a buffer layer 103 formed in the first cell region CR_1 and the second cell region CR_2.

Among the third material layers 129, a third material layer 129 adjacent to line patterns 137 may be used as a drain select line. The line patterns 137 may be bit lines. In other embodiments, the second material layers 129 of two or more layers, which are adjacent to the line patterns 137 and are successively stacked, may be used as drain select lines. Among the third material layers 129, at least one third material layer 129 adjacent to source line layers 301 may be used as a source select line. Furthermore, the remaining third material layers 129, other than the third material layers 129 used as the drain select line and the source select line, may be used as word lines.

Each channel structure 125 may penetrate the corresponding gate stacked body GST in the third direction TD, which is the vertical direction, and the first end of the channel structure 125 may be formed to protrude higher than the corresponding gate stacked body GST. The channel structure 125 may be formed in a hollow type. The channel structure 125 may include a core insulating layer 121 configured to fill a central region of the channel structure 125, a capping conductive layer 123 disposed under the core insulating layer 121, a channel layer 119 enclosing the surfaces of the core insulating layer 121 and the capping conductive layer 123, and a memory layer 117 enclosing the sidewall of the channel layer 119. The channel layer 119 may be used as a channel region for a cell string corresponding thereto. The channel layer 119 may be formed of a semiconductor material. In an embodiment, the channel layer 119 may include a silicon layer. The channel structure 125 may be formed to protrude higher than the interlayer insulating layer disposed in the uppermost portion of the corresponding gate stacked body GST. The channel structure 125 may be formed to penetrate the buffer layer 103 formed on the corresponding gate stacked body GST. The protruding end of the channel structure 125 may be formed to directly contact the corresponding source line layer 301. For example, the channel layer 119 of the channel structure 125 may be formed to be directly coupled to the source line layer 301.

The memory layer 117 may include a tunnel insulating layer enclosing the sidewall of the channel layer 119, a data storage layer enclosing the tunnel insulating layer, and a blocking insulating layer enclosing the data storage layer. The memory layer 117 may be formed to have the same length as the channel structure 125 in the vertical direction.

The word line connection structure WL_CS may be disposed on the gate stacked bodies GST. The word line connection structure WL_CS may include source line layers 301 coupled to the channel structures 125, a plurality of insulating layers 303 and 307 configured to cover the source line layers 301 and the gate stacked bodies GST, first contacts 305A penetrating the insulating layer 303 to couple the source line layers 301 to first contact pads 309A, and second contacts 305B penetrating the insulating layer 303 to couple respective word line extensions WL_EXT exposed to the upper surfaces of the gate stacked bodies GST to second contact pads 309B. Because respective word line extensions WL_EXT are exposed to the upper surfaces of the gate stacked bodies GST, the second contacts 305B for coupling the third material layers 129 of the gate stacked bodies GST to the second contact pads 309B may be disposed only on the gate stacked bodies GST without needing to extend into the gate stacked bodies GST. That is, the second contacts 305B may be disposed only at the position equal to or higher than that of the upper surfaces of the gate stacked bodies GST.

The bit line connection structure BL_CS may be disposed under the gate stacked bodies GST. The bit line connection structure BL_CS may include a first insulating layer 131, a second insulating layer 135, contact plugs 133, and line patterns 137. The line patterns 137 used as bit lines may be coupled to respective channel structures 125 through the contact plugs 133 penetrating the first insulating layer 131.

The first coupling structure 1st_CS may be disposed under the bit line connection structure BL_CS. The first coupling structure 1st_CS may include a first insulating structure 141 including a plurality of insulating layers 141A to 141D, first connection structures 143, 145, 147, and 149 formed in the first insulating structure 141, and the first connection structures 143, 145, 147, and 149 may be electrically connected to each other through contact plugs (not illustrated). The first connection structures 143, 145, 147, and 149 may include one or more first bonding metals 149 having a surface exposed to the outside of the first insulating structure 141.

The lower structure U may include a complementary metal oxide semiconductor (CMOS) circuit structure CMOS including a plurality of transistors 200 formed on a second substrate 201, and a second coupling structure 2nd_CS formed on the CMOS circuit structure CMOS. The plurality of transistors 200 may be formed in respective active regions of the second substrate 201 partitioned by isolation layers 203.

The second coupling structure 2nd_CS may include a second insulating structure 211 and second connection structures 220 formed in the second insulating structure 211. The second connection structures 220 may include various conductive patterns 213, 215, 217, 219, 221, and 223 that are embedded in the second insulating structure 211. The second insulating structure 211 may include two or more insulating layers 211A to 211D which are sequentially stacked.

The upper structure T and the lower structure U may have a structure in which they are adhered to each other through a bonding structure. For example, the exposed conductive patterns 149 of the first coupling structure 1st_CS of the upper structure T and the exposed conductive patterns 223 of the second coupling structure 2nd_CS of the lower structure U may be disposed to face each other, and may be adhered to each other. The one or more first bonding metals 149 and the one or more conductive patterns 223 may be defined as a bonding metal.

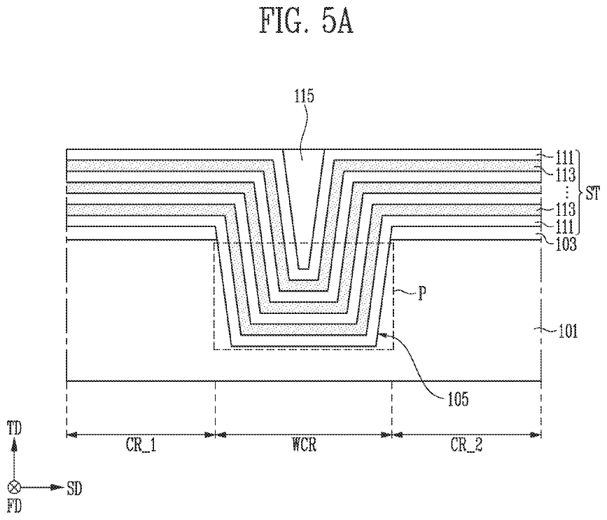

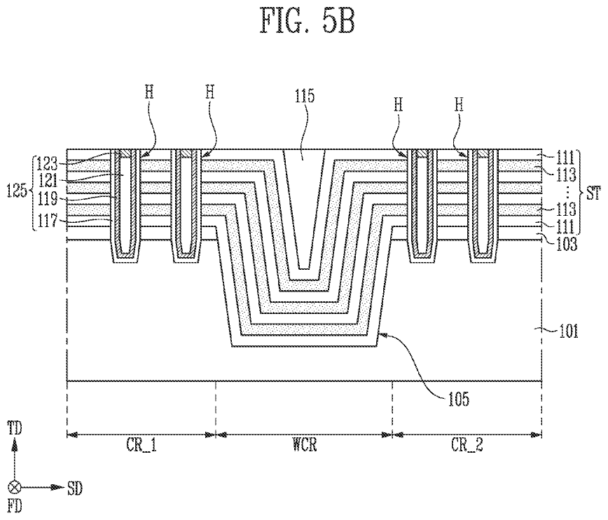

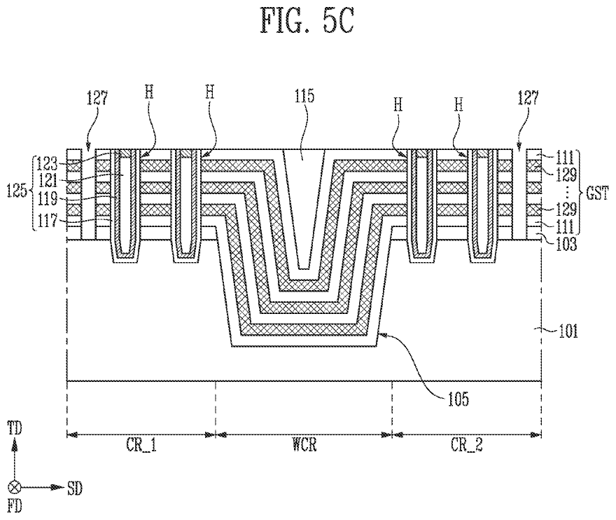

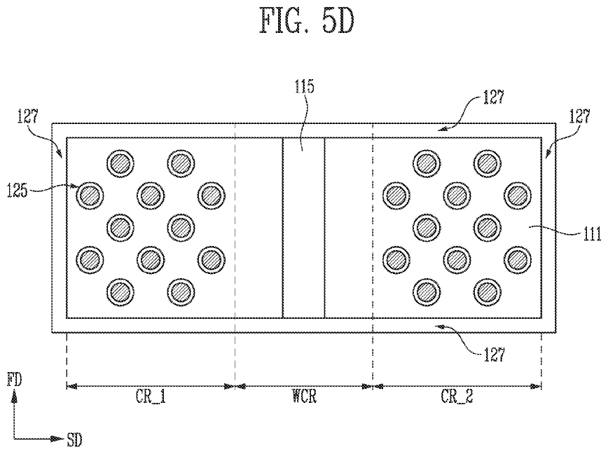

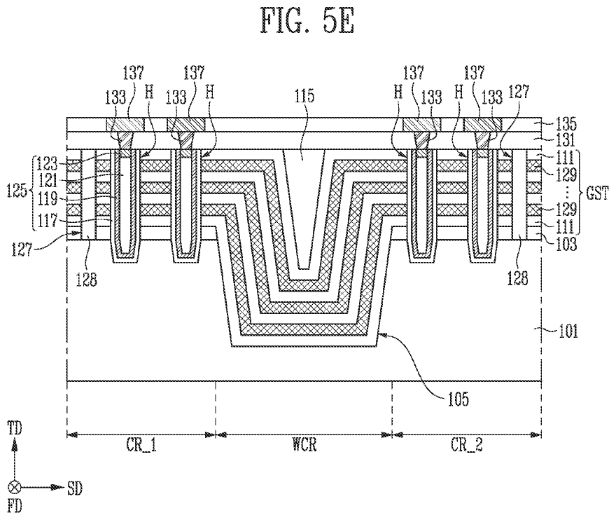

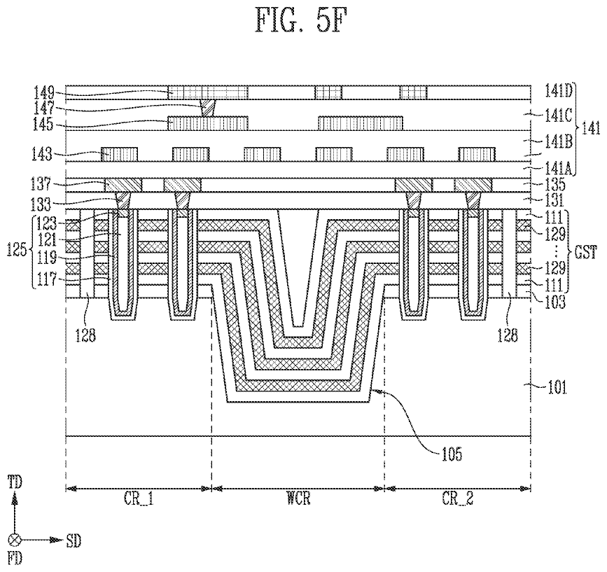

FIGS. 5A to 5F, 6, 7, 8A, and 8B are sectional views and a plan view for explaining a method of manufacturing a semiconductor memory device according to an embodiment of the present disclosure.

FIGS. 5A to 5F are sectional views and a plan view for explaining the step of forming a memory cell array, a first line array, and first connection structures on a first substrate.

Referring to FIG. 5A, a buffer layer 103 may be formed on a first substrate 101 including a first cell region CR_1, a second cell region CR_2, and a word line contact region WCR. The first substrate 101 may include silicon. The buffer layer 103 may include oxide.

Thereafter, a trench 105 may be formed in the first substrate 101 by sequentially etching the buffer layer 103 and the first substrate 101 in the word line contact region WCR. The depth of the trench 105 may be formed to be greater than the thickness of a stacked body ST to be subsequently formed.

Thereafter, the stacked body ST may be formed by alternately stacking first material layers 111 and second material layers 113 on top of one another on the buffer layer 103 and the trench 105. The first material layers 111 and the second material layers 113 may be made of materials having etching rates different from that of the first substrate 101.

In an embodiment, the first material layers 111 may include an insulating material for interlayer insulating layers. The second material layers 113 may include a material having an etching rate different from that of the first material layers 111. For example, the first material layers 111 may include silicon oxide, and the second material layers 113 may include silicon nitride. Although the following drawings illustrate embodiments in which the first material layers 111 are formed of the insulating material and the second material layers 113 are formed of sacrificial layers, the present disclosure is not limited thereto. The material properties of the first material layers 111 and the second material layers 113 may be variously changed. For example, the first material layers 111 may include an insulating material for interlayer insulating layers, and the second material layers 113 may include a conductive material for conductive patterns.

The stacked body ST may be formed on the buffer layer 103 in the first cell region CR_1 and the second cell region CR_2, and may be formed along the sidewall and the lower surface of the trench 105 in the word line contact region WCR. The stacked body ST may include a protrusion P extending into the first substrate 101 in the word line contact region WCR. Accordingly, the second material layers 113 may extend in parallel to a second direction SD in the first cell region CR_1 and the second cell region CR_2, and may extend into the first substrate 101 in the word line contact region WCR. That is, the second material layers 113 may extend in a third direction TD or in a direction between the third direction TD and the second direction SD in the word line contact region WCR.

The position of the lowest upper surface, among upper surfaces of the stacked body ST formed in the trench 105, may be lower than that of the lower surface of the buffer layer 103 in the first cell region CR_1 and the second cell region. Among the second material layers 113 included in the stacked body ST, one second material layer 113 disposed in the uppermost portion may extend to a position, deeper than the upper surface of the first substrate 101 in the first cell region CR_1 and the second cell region CR_2, in the word line contact region WCR.

The central region of the trench 105 may be filled with an insulating layer 115. The insulating layer 115 may include oxide.

Referring to FIG. 5B, in the first cell region CR_1 and the second cell region CR_2, a plurality of holes H extending in a vertical direction may be formed in the stacked body ST. The plurality of holes H may pass through the buffer layer 103 to extend into the first substrate 101 to a certain depth.

The plurality of holes H may be formed in various shapes depending on an etching material used to form the plurality of holes H.

In an embodiment, the plurality of holes H may be formed using a first etching material. The etching rates of the first material layers 111 and the second material layers 113 corresponding to the first etching material may be higher than the etching rate of the first substrate 101 corresponding to the first etching material. As a result, the widths of ends of the plurality of holes H extending into the first substrate 101 may be formed to be narrower than those of the plurality of holes H passing through the first material layers 111 and the second material layers 113.

Thereafter, a channel structure 125 may be formed in each of the plurality of holes H. The channel structure 125 may include a memory layer 117 and a channel layer 119, and may further include a core insulating layer 121 and a capping conductive layer 123.

In an embodiment, the memory layer 117 may be formed along the sidewall and the lower surface of each of the plurality of holes H. The memory layer 117 may be formed by sequentially stacking a blocking insulating layer, a data storage layer, and a tunnel insulating layer on the surface of each of the plurality of holes H. The memory layer 117 may be formed in a liner shape. Thereafter, the channel layer 119 may be formed on the surface of the memory layer 117. The channel layer 119 may include a semiconductor layer used as a channel region. For example, the channel layer 119 may include polysilicon. In an embodiment, the channel layer 119 may be formed in a liner shape, and the central region of each of the plurality of holes H may include a portion that is not filled with the channel layer 119. When the channel layer 119 is formed in a liner shape, the central region of each of the plurality of holes H may be filled with the core insulating layer 121 on the channel layer 119. Thereafter, a recess region may be defined by partially etching an upper portion of the core insulating layer 121, and the capping conductive layer 123 may be formed in the recess region. The core insulating layer 121 may include oxide, and the capping conductive layer 123 may include conductive dopants. The conductive dopants may include an n-type dopant for junctions. The conductive dopants may include a counter-doped p-type dopant.

In other embodiments, the channel layer 119 may be formed to fill the central region of each of the plurality of holes H, wherein the core insulating layer 121 and the capping conductive layer 123 may be omitted.

Referring to FIGS. 5C and 5D, slits 127 passing through the first material layers 111 and the second material layers (e.g., 113 of FIG. 5B) in the third direction TD may be formed. The slits 127 may extend in the second direction SD. The sidewalls of the second material layers (e.g., 113 of FIG. 5B) formed in the first cell region CR_1 and the second cell region CR_2 may be exposed through the slits 127.

Subsequently, the second material layers (e.g., 113 of FIG. 5B) exposed through the slits 127 may be selectively removed, and thus horizontal spaces may be defined. The horizontal spaces may be defined between the first material layers 111 neighboring each other in a vertical direction.

Thereafter, the horizontal spaces from which the second material layers (e.g., 113 of FIG. 5B) are removed may be filled with third material layers 129 through the slits 127. The first material layers 111 and the third material layers 129, which are alternately stacked, may be defined as a gate stacked body GST. The third material layers 129 may be made of a conductive material. For example, the third material layers 129 may contain a metal material.

As described above, the gate stacked body GST may be formed on the first substrate 101 by replacing the second material layers 113 as sacrificial layers with the third material layers 129. The gate stacked body GST may include a structure in which the first material layers 111, as interlayer insulating layers, and the third material layers 129, as conductive patterns, are alternately stacked. The gate stacked body GST may be penetrated by the channel structures 125, and the channel structures 125 may extend into the first substrate 101.

Referring to FIG. 5E, the slits 127 may be filled with an insulating material, whereby insulating patterns 128 may be formed. Thereafter, a first insulating layer 131 that covers the gate stacked body GST, the insulating patterns 128, the channel structures 125, and the insulating layer 115 may be formed. The first insulating layer 131 may include oxide.

Thereafter, contact plugs 133 penetrating the first insulating layer 131 may be formed. The contact plugs 133 may extend to contact the channel structures 125, respectively. Subsequently, a second insulating later 135 that covers the contact plugs 133 may be formed. The second insulating layer 135 may include oxide. Then, line patterns 137 to be respectively coupled to the contact plugs 133 may be formed in the second insulating layer 135. The line patterns 137 may be bit lines coupled to the contact plugs 133.

Referring to FIG. 5F, a first insulating structure 141 that covers the line patterns 137 may be formed. The first insulating structure 141 may include two or more insulating layers 141A to 141D. First connection structures 143, 145, 147, and 149 may be embedded in the first insulating structure 141, and may be electrically connected to each other through contact plugs (not illustrated).

The first connection structures 143, 145, 147, and 149 may include first bonding metal 149 having a surface exposed to the outside of the first insulating structure 141.

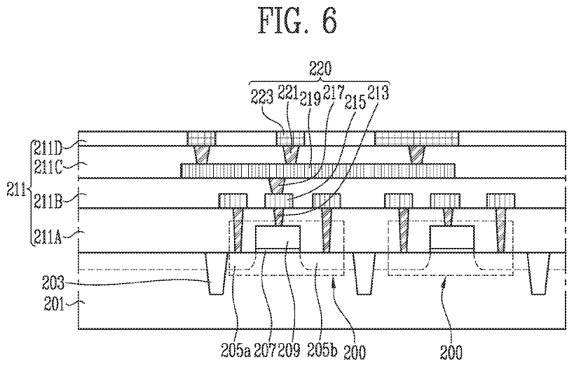

FIG. 6 is a sectional view for explaining the step of forming a CMOS circuit and second connection structures on a second substrate.

Referring to FIG. 6, a plurality of transistors 200 constituting a complementary metal oxide semiconductor (CMOS) circuit may be formed on a second substrate 201.

The second substrate 201 may be a bulk silicon substrate, a silicon-on-insulator substrate, a germanium substrate, a germanium-on-insulator substrate, a silicon-germanium substrate, or an epitaxial layer substrate formed using a selective epitaxial growth method.

The transistors 200 may be formed in respective active regions of the second substrate 201 partitioned by isolation layers 203. Each of the transistors 200 may a gate insulating layer 207 and a gate electrode 209 stacked in the active region corresponding thereto and junctions 205a and 205b formed in active regions disposed on both sides of the gate electrode 209. Each of the junctions 205a and 205b may include conductive dopants for implementing a transistor corresponding thereto. Each of the junctions 205a and 205b may include at least one of an n-type dopant and a p-type dopant.

After the plurality of transistors 200 are formed, second connection structures 220 coupled to the transistors 200 constituting the CMOS circuit, and a second insulating structure 211 configured to cover the second connection structures 220 and the transistors 200 may be formed.

The second insulating structure 211 may include two or more insulating layers 211A to 211D. The second connection structures 220 may be embedded in the second insulating structure 211. Each of the second connection structures 220 may include a plurality of conductive patterns 213, 215, 217, 219, 221, and 223. The second insulating structure 211 and the second connection structures 220 may be changed in various forms without being limited to the example illustrated in the drawing.

The conductive patterns 213, 215, 217, 219, 221, and 223 included in each of the second connection structures 220 may include second bonding metal 223 having a surface exposed to the outside of the second insulating structure 211.

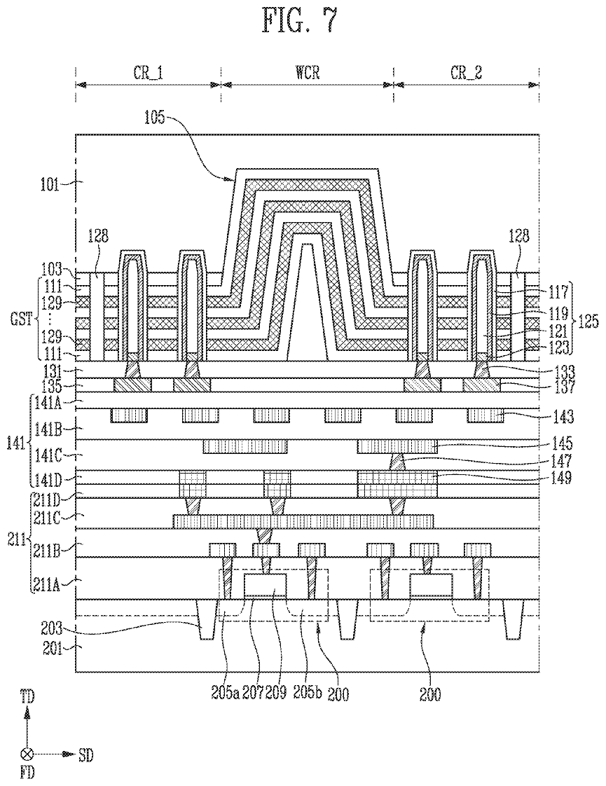

FIG. 7 is a sectional view for explaining the step of adhering the first connection structures and the second connection structures to each other.

Referring to FIG. 7, the first substrate 101 and the second substrate 201 are aligned such that first the bonding metal 149 on the first substrate 101 and the second bonding metal 223 on the second substrate 201 can contact each other. The first bonding metal 149 and the second bonding metal 223 may contain various types of metal materials, for example, copper.

Thereafter, the first bonding metal 149 and the second bonding metal 223 are adhered to each other. For this, after heat is applied to the first bonding metal 149 and the second bonding metal 223, the first bonding metal 149 and the second bonding metal 223 may be hardened. The present disclosure is not limited thereto, and various processes of coupling the first bonding metal 149 and the second bonding metal 223 to each other may be introduced.

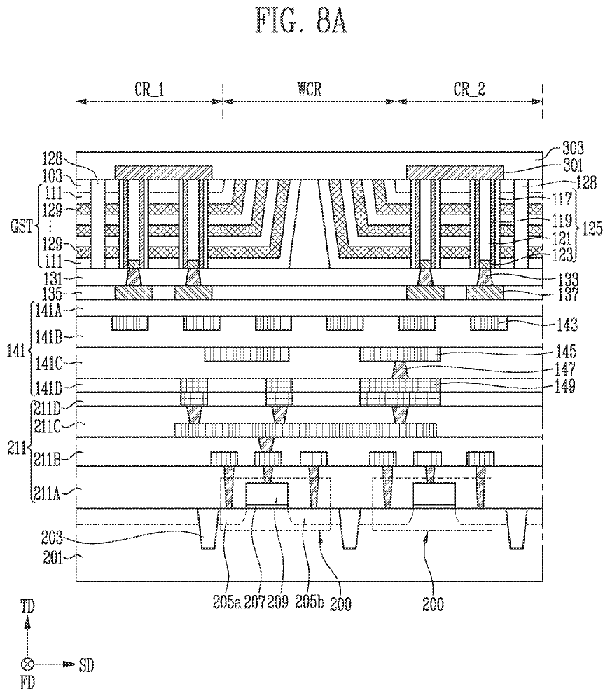

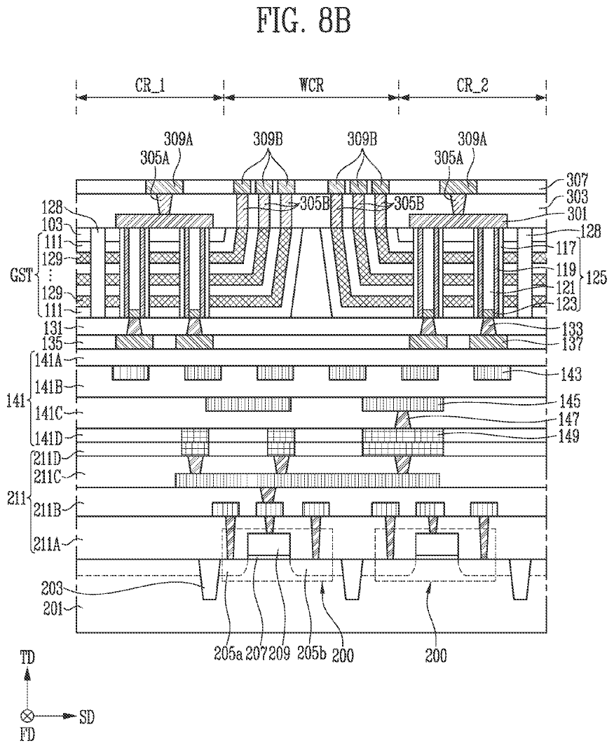

FIGS. 8A and 8B are sectional views for explaining the step of forming a line structure coupled to third material layers used as conductive patterns of gate stacked bodies GST.

Referring to FIG. 8A, the first substrate 101 illustrated in FIG. 7 may be removed. For example, the first substrate (e.g., 101 of FIG. 7) may be removed by performing a grinding process, wherein the grinding process may be performed to expose the buffer layer 103. Due thereto, a portion of each gate stacked body GST extending into the first substrate (e.g., 101 of FIG. 7) in the word line contact region WCR may be removed together with the first substrate (e.g., 101 of FIG. 7). For example, each gate stacked body GST in the word line contact region WCR may remain only at the position of the upper surface of the buffer layer 103, and portions of the gate stacked body GST disposed higher than the position of the upper surface of the buffer layer 103 may be removed together with the first substrate (e.g., 101 of FIG. 7). Through the grinding process, respective ends of the third material layers 129 in the gate stacked body GST disposed in the word line contact region WCR may be exposed to the external surface of the gate stacked body GST. Each of the third material layers 129 may extend in the third direction TD or in the direction between the third direction TD and the second direction SD in the word line contact region WCR, and the cross-section of an extending portion may be exposed to the external surface of the gate stacked body GST. In this case, the height of the upper surface of the buffer layer 103 may be decreased by performing an additional etching process, and thus respective ends of the third material layers 129 in the word line contact region WCR may extend up to a position equal to or higher than that of the upper surface of the buffer layer 103. In an embodiment, the height of the upper surface of the buffer layer 103 may be decreased by performing an additional etching process, and thus respective ends of the third material layers 129 in the word line contact region WCR may extend up to a position equal to or higher than that of the upper surface of the buffer layer 103 as shown in FIG. 8A.

Portions of the channel structures 125 protruding higher than the buffer layer 103 may be etched together in the above-described grinding process, whereby respective channel layers 119 of the channel structures 125 may be exposed.

Thereafter, source line layers 301 contacting respective channel layers 119 of the channel structures 125 may be formed. Each of the source line layers 301 may be formed of a polysilicon layer doped with N-type impurities. Thereafter, an insulating layer 303 configured to cover the source line layers 301 and the gate stacked bodies GST may be formed. The insulating layer 303 may include oxide.

Referring to FIG. 8B, contact holes through which portions of the source line layers 301 are exposed and contact holes through which respective cross-sections of the third material layers 129 are exposed may be formed by performing an etching process. For example, the contact holes through which the portions of the source line layers 301 are exposed by passing through the insulating layer 303 and the contact holes through which respective cross-sections of the third material layers 129 exposed to the external surfaces of the gate stacked bodies GST are exposed by passing through the insulating layer 303 are exposed may be formed. Thereafter, first contacts 305A and second contacts 305B may be formed in the contact holes. That is, the first contacts 305A penetrating the insulating layer 303 to contact the source line layers 301 and the second contacts 305B contacting respective cross-sections of the third material layers 129 exposed to the external surfaces of the gate stacked bodies GST may be formed.

Thereafter, an insulating layer 307 covering the first contacts 305A and the second contacts 305B may be formed on the insulating layer 303, and first contact pads 309A and second contact pads 309B coupled to the first contacts 305A and the second contacts 305B, respectively, may be formed in the insulating layer 307.

As described above, according to the embodiment of the present disclosure, the third material layers 129 used as word lines may be formed to extend in the direction of the surfaces of the gate stacked bodies GST in the word line contact region WCR, and may be formed such that the ends of the third material layers 129 are exposed in the word line contact region WCR during the process of removing the first substrate (e.g., 101 of FIG. 7). Accordingly, the third material layers 129 of the gate stacked bodies GST may be coupled to the second contacts 305B without requiring a separate contact plug forming process.

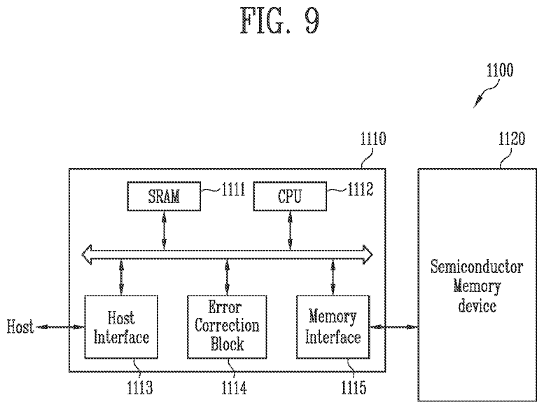

FIG. 9 is a block diagram illustrating the configuration of a memory system according to an embodiment of the present disclosure.

Referring to FIG. 9, a memory system 1100 includes a semiconductor memory device 1120 and a memory controller 1110.

The semiconductor memory device 1120 may be a multi-chip package composed of a plurality of flash memory chips. The semiconductor memory device 1120 may be the semiconductor memory devices described with reference to FIGS. 1 to 4.

The memory controller 1110 may control the semiconductor memory device 1120, and may include a static random access memory (SRAM) 1111, a central processing unit (CPU) 1112, a host interface 1113, an error correction block 1114, and a memory interface 1115. The SRAM 1111 may be used as a working memory of the CPU 1112, the CPU 1112 may perform overall control operations for data exchange of the memory controller 1110, and the host interface 1113 may be provided with a data exchange protocol of a host coupled to the memory system 1100. Further, the error correction block 1114 detects and corrects an error included in data that is read from the memory device 1120, and the memory interface 1115 interfaces with the memory device 1120. In addition, the memory controller 1110 may further include a read only memory (ROM) or the like that stores code data for interfacing with the host.

The above-described memory system 1100 may be a memory card or a solid state drive (or a solid state disk: SSD) in which the semiconductor memory device 1120 and the memory controller 1110 are combined with each other. For example, when the memory system 1100 is an SSD, the memory controller 1110 may communicate with an external device (e.g., host) through one of various interface protocols, such as universal serial bus (USB), multimedia card (MMC), peripheral component interconnection-express (PCI-E), serial advanced technology attachment (SATA), parallel advanced technology attachment (PATA), a small computer system interface (SCSI), an enhanced small disk interface (ESDI), and Integrated Drive Electronics (IDE).

According to an embodiment of the present disclosure, by extending a plurality of interlayer insulating layers and a plurality of conductive patterns, which extend in a horizontal direction in a cell region, in a vertical direction in a word line contact region, the plurality of interlayer insulating layers and the plurality of conductive patterns may be exposed to the upper surface or the lower surface of a gate stacked body, thus enabling the conductive patterns to be coupled to contacts.

What is claimed is:

1. A semiconductor memory device, comprising:
a gate stacked body in which a plurality of interlayer insulating layers and a plurality of conductive patterns are alternately stacked; and
a plurality of channel structures disposed to extend in a vertical direction in the gate stacked body, the channel structures disposed in a cell region,
wherein, in the cell region, the plurality of conductive patterns extend in a horizontal direction, and
wherein, in a word line contact region adjacent to the cell region, the plurality of conductive patterns extend in the vertical direction or in a direction between the vertical direction and the horizontal direction.

2. The semiconductor memory device according to claim 1, wherein respective ends of the plurality of conductive patterns extending in the vertical direction or in the direction between the vertical direction and the horizontal direction are exposed to an external surface of the gate stacked body.

3. The semiconductor memory device according to claim 2, further comprising:
a plurality of contacts coupled to the plurality of conductive patterns, respectively,
wherein each of the plurality of second contacts is disposed on the gate stacked body in the word line contact region.

4. The semiconductor memory device according to claim 3, wherein the plurality of contacts are coupled to respective ends of the plurality of conductive patterns exposed to the external surface of the gate stacked body.

5. The semiconductor memory device according to claim 1, further comprising:
an insulating layer configured to separate the gate stacked body in the word line contact region.

6. The semiconductor memory device according to claim 5, wherein the insulating layer extends in the vertical direction.

7. The semiconductor memory device according to claim 1, further comprising:
a source line layer disposed on the gate stacked body and coupled to respective upper portions of the plurality of channel structures; and
a bit line connection structure disposed under the gate stacked body and coupled to respective lower portions of the plurality of channel structures.

8. The semiconductor memory device according to claim 7, further comprising:
a first coupling structure coupled to the bit line connection structure, and including a first bonding metal, a surface of which is exposed to outside of the first coupling structure;
a second coupling structure including a second bonding metal contacting the first bonding metal of the first coupling structure; and
a complementary metal-oxide semiconductor (CMOS) circuit structure coupled to the second coupling structure and including a plurality of transistors.

9. The semiconductor memory device according to claim 7, further comprising:
a buffer layer disposed between an upper portion of the gate stacked body in the cell region and the source line layer,
wherein the plurality of channel structures are coupled to the source line layer by penetrating the buffer layer.

10. The semiconductor memory device according to claim 1, wherein the plurality of conductive patterns extending in the horizontal direction in the cell region and the plurality of conductive patterns extending in the vertical direction or in the direction between the vertical direction and the horizontal direction in the word line contact region are made of substantially an identical material.

11. A semiconductor memory device, comprising:
a gate stacked body formed in a cell region and in a word line contact region adjacent to the cell region in a horizontal direction; and
a plurality of channel structures disposed to extend in a vertical direction in the gate stacked body, the channel structures disposed in the cell region,
wherein the gate stacked body includes a plurality of interlayer insulating layers and a plurality of conductive patterns that are alternately stacked, and
wherein, in the cell region, the plurality of conductive patterns extend in the horizontal direction, and
wherein, in the word line contact region, the plurality of conductive patterns extend in the vertical direction or in a direction between the vertical direction and the horizontal direction and are then exposed to an upper surface of the gate stacked body.

12. The semiconductor memory device according to claim 11, further comprising:
a plurality of contacts disposed on the gate stacked body in the word line contact region and respectively coupled to the plurality of conductive patterns exposed to the upper surface of the gate stacked body.

13. The semiconductor memory device according to claim 12, wherein the plurality of contacts are disposed at a position equal to or higher than a position of the upper surface of the gate stacked body.

14. The semiconductor memory device according to claim 11, further comprising:
an insulating layer configured to separate the gate stacked body in the word line contact region.

15. The semiconductor memory device according to claim 14, wherein the insulating layer extends in the vertical direction.

16. The semiconductor memory device according to claim 11, further comprising:
a buffer layer formed on the gate stacked body in the cell region,
wherein each of the plurality of conductive patterns extending in the vertical direction or the direction between the vertical direction and the horizontal direction in the word line contact region extends to a position equal to or higher than an upper surface of the buffer layer.

17. A method of manufacturing a semiconductor memory device, comprising:
forming a buffer layer on a substrate including a cell region and a word line contact region;
forming a trench by etching the buffer layer and the substrate in the word line contact region to a certain depth;
forming a stacked body, in which first material layers and second material layers are alternately stacked, on an entire structure, wherein the stacked body is formed along a sidewall and a lower surface of the trench and formed such that an upper surface of the stacked body in the word line contact region is lower than a lower surface of the buffer layer in the cell region;
forming a plurality of channel structures extending in a vertical direction in the stacked body and the buffer layer in the cell region;
replacing the second material layers with third material layers that are conductive patterns;
removing the substrate such that the lower surface of the buffer layer is exposed, and removing a portion of the stacked body disposed at a position lower than the lower surface of the buffer layer, together with the substrate, thus exposing the third material layers; and
forming contacts coupled to the exposed third material layers, respectively.

18. The method according to claim 17, wherein forming the trench comprises:
etching the substrate such that a depth of the trench is greater than a thickness of the stacked body.

19. The method according to claim 17, wherein removing the substrate comprises:
exposing the lower surface of the buffer layer by performing a grinding process, and etching the portion of the stacked body disposed at the position lower than the lower surface of the buffer layer, together with the substrate, thus exposing surfaces of respective ends of the plurality of second material layers formed along a sidewall of the trench.

20. The method according to claim 17, further comprising:
after forming the stacked body, forming an insulating layer on the stacked body in the trench such that a central region of the trench is embedded.

21. The method according to claim 17, wherein replacing the second material layers with the third material layers comprises:
exposing sidewalls of the second material layers by forming a slit passing through the stacked body in a vertical direction; and
removing the exposed second material layers and filling spaces from which the second material layers are removed with the third material layers.

22. The method according to claim 17, wherein removing the substrate comprises:
exposing surfaces of ends of the exposed third material layers at a position equal to or lower than a position of the lower surface of the buffer layer.
